(19) United States
(12) Patent Application Publication
(10) Pub. No.: US 2007/0184579 A1
(43) Pub. Date: Aug. 9, 2007

(54) Method of fabrication on high coplanarity of copper pillar for flip chip packaging application

(75) Inventors: Jung-Tang Huang, Taipei (TW); Pen-Shan Chao, Taipei (TW); Hou-Jun Hsu, Taipei (TW)

Correspondence Address: Jung-Tang Huang, 5F., No.7, Lane 10, Sec. 2, Bade Rd. Da-an District, Taipei City, 106, omitted

(73) Assignee: Jung-Tang Huang

(21) Appl. No.: 11/702,311

(22) Filed: Feb. 6, 2007

(30) Foreign Application Priority Data
Feb. 8, 2006 (TW) 095104212

(51) Int. Cl. H01L 21/00

(52) U.S. Cl. 438/106

(57) ABSTRACT

This invention is characteristic of combining an electroplating process with a polishing process to uniformly fabricate multi-layer flip chip copper pillar. All kinds of flip chip copper pillar with varied shapes and sizes are able to be defined by using multi-layer photolithography process commonly utilized in the semiconductor processes. After that, use both exposure and alignment procedures to accurately define multi-layer photoresist's patterns on the substrate. Some designated metallic materials are then electroplated on those completed well-defined patterns during the last photolithography process by means of an electroplating process. A polishing process follows the electroplating to level the rugged solder bumps, resulted from the impact on the certain changeable and inevitable electroplating parameters. The first layer of evenly polished flip chip copper pillar could be used as a base metal to continuously deposit another separate flip chip copper pillar that may have different materials as well as heights from the first one. Similarly, the second upper layer of flip chip copper pillar is capable of being uniformly polished employing the same polishing mechanism as the first one. High coplanarity of multi-layer electroplating-based flip chip copper pillar suitable to be used in the high-end and advanced three-dimensional electronic packaging will be achieved after finishing the final reflow process.

### BACKGROUND

1. Field of Invention

The present invention relates to an electronic packaging technology and, more specifically, relates to a bumping process used for manufacturing high coplanarity and uniform size copper pillar for flip chip packaging application.

2. Description of Related Art

There are three mainstreams of electronic packaging technologies including Dual-in-Level Packaging (DIP), Surface Mount Component (SMC) and Chip on Board (COB). COB, a kind of much more advanced packaging process, refers to the semiconductor assembly technology wherein the microchip or die is directly mounted on and electrically interconnected to its final circuit board, instead of undergoing traditional assembly or packaging as an individual IC. Flip chip packaging, wire bonding and taped automated bonding are its three major skeletons. Advantages offered by COB technology include: (1) reduced space requirements; (2) reduced cost; (3) better performance due to decreased interconnection lengths and resistances; (4) higher reliability due to better heat distribution and a lower number of solder joints; (5) shorter time-to-market; and (6) better protection against reverse-engineering.

With increasing demands for cheaper, smaller, faster, portable, and yet multi-featured electronic consumer devices/products, flip chip technology utilization in high-density packaging is inevitable. Flip chip assembly, therefore, is said to be widely recognized as the most common and potential packaging technology aimed at performing high-density and high-end electronic packaging. In order to pursue electronic products with smaller size and lighter weight, many worldwide researchers and experts have dedicated themselves around the clock to researching this cutting-edge packaging. Issues include the use of flip chip for silicon with low-k dielectrics, availability of low-cost organic substrates, and the adoption of Pb-free bumping process.

Flip chip packaging process, in essence, adopts numerous array of solder bumps mounted on the chips or substrates to serve as I/Os to instead of utilizing those commonly-seen lead frame and Au wire to connect pads with devices. This innovative packaging process originated in the early 1960s invented by IBM enables notable reduction in substrate size as well as increase in number of I/Os along with the shrinkage of pitch size of solder bumps. The other advantages include excellent electrical performance, shorter interconnection lengths, extremely low-inductance, better electromagnetic shielding effectiveness, self-alignment, collective process and lower cost

At the beginning of 2006, Intel officially announced to use advanced multiple copper pillar to instead of traditional single-layer Sn—Pb solder bump to form interconnections between die and board in Presler and Yonah processors.

Basically, copper pillar surpassing the usual single-layer Sn—Pb solder bump in terms of electrical and thermal characteristics combines special cylindrical connections with another layer of solder or lead-free caps to form the connecting elements. Furthermore, they enable the dies far away from the substrate, largely diminishing the occurrence of tin whiskers.

Copper pillar could be further categorized into two types, non-reflowable and reflowable, the former deliver higher packaging reliability since standoff can be easily maintained. In most cases, the elongated copper portion is manufactured with a height of 50˜70 um and the solder on the tip had better being set between 20 to 35 um in height for the purpose of bringing higher yield and reliability.

Major bumping processes include electroplating, stencil printing, evaporation and electroless. Besides, stud bumping, solder ball bumping, immersion and transfer are also applicable to form solder bumps. Of all the bumping processes, electroplating is, so to speak, by far the most commercially viable process to fabricate either traditional single-layer solder bump or state-of-the-art multiple copper pillar for its higher deposition rate and smaller pitch size. Additionally, simple manipulation, high yield and mass productivity are also its benefits.

However, the coplanarity or it is called uniformity is generally inferior to its other counterparts such as stencil printing, electroless, evaporation, laser jetting and squeegee bumping, mostly implicated by its non-predictable and variable plating parameters in the plating bath. The coplanarity no matter on advanced multi-layer copper pillars or on conventional mono-layer Sn-based or lead-free solder bumps, however, plays an important role in joint reliability after packaging. Fine pitch solder bumps, wafer level packaging (WLP) and large-scale substrates are particularly sensitive to this issue.

Such perplexing difficulty is mainly blamed on the non-uniform electric current density distribution, which is especially serious on the micro-scale patterns. This common non-uniform electric current density distribution is not affected by only one factor but by various plating parameters consisting of plating bath design, chemical additives, magnitude of current density, use of current type, distance between cathode and anode, agitation method, chemical maintenance, pre-cleaning solution, configurations, arrangements and volumes of patterns, high aspect ratio and so on. Generally, it's not easy to eliminate or control the height deviation within the range of 5 um throughout the whole substrate no matter how sophisticated plating facility is adopted, not to mention to add leveling agent, wetting agent or brighter to the changeable plating bath.

The process capability for plating-based flip chip solder bump in coplanarity control in the global packaging markets shows that the coplanarity of solder bump could be merely controlled close to 15˜20% in wafer to wafer, 10% in wafer and 5% in die respectively.

Three different solutions have been disclosed to solve the annoying non-uniform coplanarity of plating-based flip chip solder bump. The first solution to the foregoing problem is disclosed in U.S. Pat. No. 6,348,401, entitled “METHOD OF FABRICATING SOLDER BUMPS WITH HIGH COPLANARITY FOR FLIP-CHIP APPLICATION”, which adopts a two-step deposition method to prevent the mushroom-like structures, generally discovered in the case of high aspect ratio micro-electroplating due to poor electric current distribution. It's involved in using a first step of electroplating solder over UBM pads to a controlled height still below the topmost surface of the mask, and a second step of screen-printing solder paste over the electroplated solder layer. The drawback of this invention is that the use of screen-printing would put a series limitation on pitch size of solder bump.

The second solution to the foregoing problem is disclosed in U.S. Pat. No. 6,957,127, entitled “PACKAGING AND TESTING OF BGA PACKAGES”, which is characterized by utilizing probe tips that are previously planarized using a precision process such as chemical mechanical polishing (CMP) to press the non-uniform solder bump directly. As far as the fine pitch solder bump is concerned, pressing it directly may damage either substrate or solder bump itself. Further, the neighboring pressed solder bumps with fine pitch size would be forcedly touched together because of expansion in the horizontal direction.

The final solution to the foregoing problem is disclosed in U.S. Pat. No. 6,975,016, entitled “WAFER BONDING USING A FLEXIBLE BLADDER PRESS AND THINNED WAFERS FOR THREE-DIMENSIONAL (3D) WAFER-TO-WAFER VERTICAL STACK INTEGRATION AND APPLICATION THEREOF”, which features in applying a flexible bladder press containing high pressure gas to account for the height differences of the metal bonding layer. Similarly, pressing solder bumps with different height directly is harmful to essential future trend for pursuing finer pitch size of flip chip solder bump.

Seeing that at present there is lack of any effective measure to solve solder bumps' coplanarity after electroplating, this invention thus provides an innovative CMP-like polishing process, which differs greatly from the CMP process that only focuses on nm-scale polishing in the semiconductor field. On the contrary, predominately in mechanical polishing force enables it to polish much wider height difference of mushroom-like shapes after electroplating. The most important thing is that it owns 100 times cheaper in price as well as 50 times faster in material removal rate (MRR) respectively than CMP.

Thoroughly improving coplanarity after electroplating could pave the way for obtaining better reliability and yield in electronic packaging. At the same time, only getting excellent coplanaity and smooth surface roughness to plating-based devices are we eligible to enter the next generation of electronic industry in pursuit of smaller pitch size, larger I/Os and multiple functions.

### SUMMARY

It is therefore an object of the present invention to provide a bumping process to improve the overall coplanarity of plating-based copper pillars. The foregoing copper pillars bumping process is characteristic of utilizing a polisher to planarize the electroplated copper pillars with height variation and rough surface, and change them into the new ones with the combination of higher coplanarity and smoother surface.

The present invention utilizes a polisher that is able to planarize wider height variation aroused from certain changeable plating parameters between the nearest two copper pillar and even across the whole substrate.

The invention provides a bumping process for making high coplanarity electroplated copper pillar by using a polisher comprising the steps of: (1) depositing two thin metallic layers such as Chromium (Cr) and Copper (Cu) on the surface of the substrate to serve as UBMs; (2) coating the first layer of Photoresist (PR) to the desired thickness and then conducting a series of photolithography processes to define the patterns of copper pillars for electroplating; (3) filling the opening holes left after developing by electroplating; (4) utilizing the proposed polisher to level off the non-uniform coplanarity and rugged electroplated surface; (5) coating the second layer of PR with using the similar method as the previous one; (6) exposing, baking and developing to define the upper cup of the copper pillars and then plating the second upper cup onto the first layer of Cu-based pillars with either Sn—Pb or Pb-free Sn-based metals or alloys; (7) planarizing the second electroplated upper cup again by polishing to the desired dimension; (8) assisted by a supersonic to remove the remains of PR layer and UBMs by immersing the substrate into stripper and other chemical like acetone; (9) conducting the final reflow process, if necessary.

The substrate after electroplating is fixed on the polishing fixture and then faces it down on the polishing pad of the polisher. Loading a pressure onto the polishing fixture and spraying slurry uniformly on the polishing pad are subsequently operated.

By installing this extra polishing process in the wake of electroplating is capable of forming two future state-of-the-arts solder bumps, multi-layer and fine pitch (defined below 100 um bump's center to bump's center). As a result of multi-layer electroplating, the former naturally exhibits huger accumulated deviation, worsening the overall coplanarity among electroplated copper pillars. With the pitch size sharply diminished below 100 um, the later, on the other hand, is likely to suffer either short circuit due to over-electroplating or broken circuit caused by poor coplanarity, both of which extremely affect reliability and yield of electroplated copper pillars after packaging.

With the help of this polisher, the coplanarity throughout the global 4 inch silicon wafer could be controlled approximately to ±2.5 um, and each single die (6 mm×6 mm) could also be controlled within 1 um.

### BRIEF DESCRIPTION OF DRAWINGS

The detailed drawings of this invention will be fully understood from the following descriptions wherein:

FIG. 1 is a flow chart showing the whole procedures of this invention.

FIGS. 2A-2K are schematic diagrams depicting the whole procedures involved in forming plated high coplanarity of flip chip copper pillar step by step.

FIG. 3 is a schematic diagram of the polisher used to polish non-uniform plated structures.

FIG. 4 illustrates the self-designed polishing fixture and shows the relative locations of the taped flexible rubber and the outer PVC ring.

### DETAILED DESCRIPTION

Referring to the attached drawings, a preferred embodiment of the method for fabricating high coplanarity flip chip copper pillar will be illustrated in detail as follows:

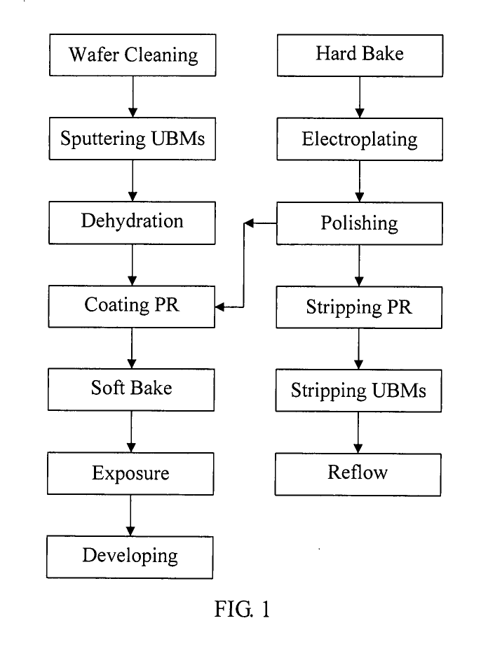

Referring to FIG. 1, The whole fabrication procedures in this invention could be further divided into seven major steps including wafer cleaning and dehydration, UBMs deposition, photolithography, electroplating, polishing, stripping PR and UBMs and reflow.

In general, wafer surface usually contains much water vapor resulting from moisture coming from atmosphere. Dehydration is a process used to reduce the water vapor from the wafer surface in order to increase the adhesive ability between wafer and PR. The method is to put the substrate into heated oven or onto hot plate for 3˜5 minutes.

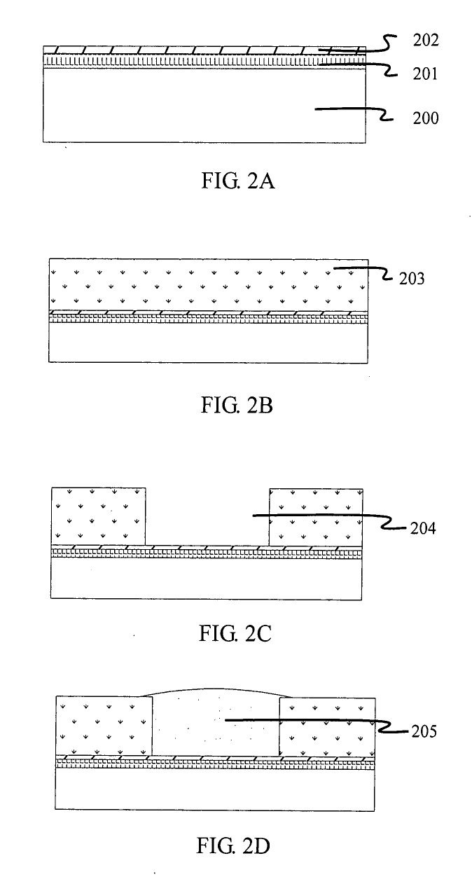

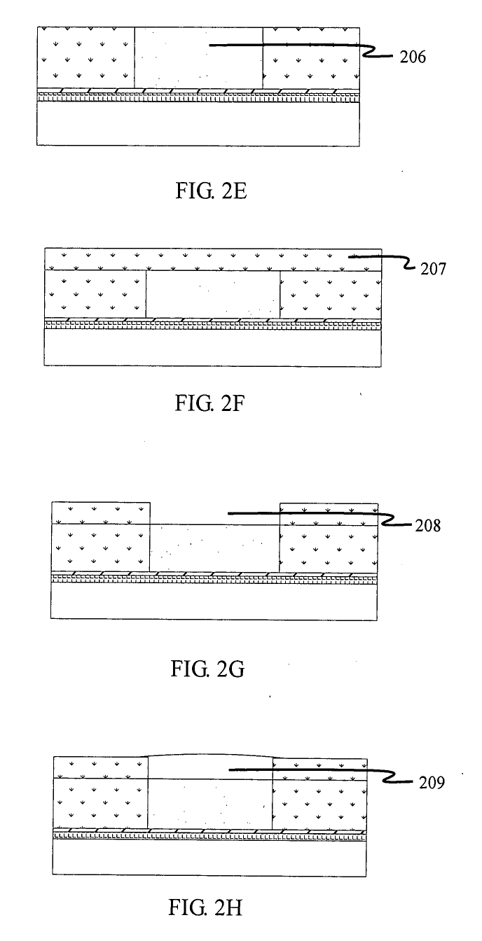

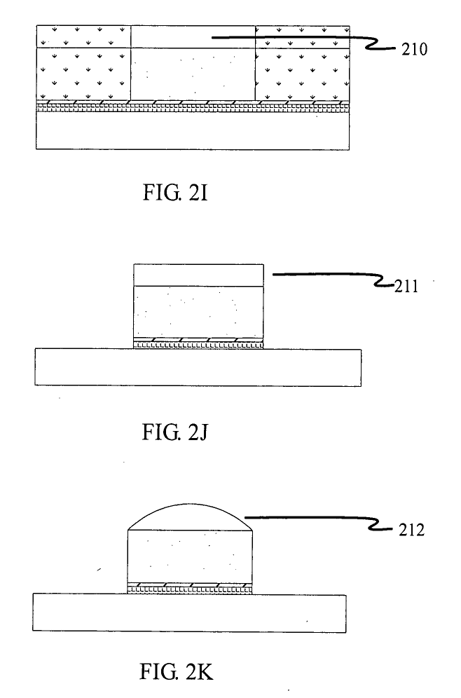

Referring to FIGS. 2A-2K, these drawings particularly present the schematic sectional diagrams step by step for the flip chip copper pillar fabrication process.

Referring to FIG. 2A, firstly, two metallic layers, Cr (0.3 um) 201 and Cu (0.3 um) 202, are evenly coated over the chip-filled substrate 200 by sputtering, evaporation or other deposition techniques. Other metals such as Ti (Titanium), W (Tungsten), Ni (Nickel) and Au (Gold) are also available to be used to form UBM layers.

Referring to FIG. 2B, next, the first layer of PR 203 is then coated about 50˜70 um on the second Cu UBM 202. PR coating in the photolithography process contains three fundamental operation steps described as follows: (1) Drop adequate PR on the substrate's center until the whole wafer is covered at least 2/3 areas; (2) Use low coating speed to spread the PR uniformly in order to acquire desired PR thickness; (3) Increase coating speed to achieve more uniform PR layer.

Referring to FIG. 2C, exposure is the next step to transform patterns from mask to substrate 200 by utilizing ultraviolet light ranging from 200˜450 nm. Afterwards, the exposed substrate 200 is immersed into PD 523 developer for several minutes to reveal the opening hole 204 (the other numerous open holes are not shown) designated for electroplating, and repeatedly stirring the developer could assure fully-developed throughout the whole substrate 200. The substrate 200 is recommended to be washed with DI water for one minute to avoid unnecessary chemical reaction between the used developer and the electroplating solution from the next process.

Referring to FIG. 2D, the opening hole 204 left after developing is totally electroplated over or at least has the same level as the first PR surface 203 with either Cu or other Cu alloys to form the first layer of electroplated copper pillar 205. Metals or alloys with good thermal conductivity such as Gold (Au), Silver (Ag), Aluminum (Al), Sn—Ag, Sn—Cu are also alternate materials. Prior to performing the electroplating process, removing oil, grease, oxide and other contaminant with 3˜5% dilute H₂SO₄ for 3 minutes from the substrate 200 could ensure getting better bonding adhesion between the substrate 200 and the electroplated first layer of copper pillar 205. The optimal electric current density for Cu electroplating is 3˜7 ASD (A/dm²) and any electric current type is available. In this case, the electroplating deposition rate reaches 0.3 um/min in 0.5 ASD, and it's almost proportional to electric current density.

For example, with a view to getting a better coplanarity among the electroplated copper pillar 205, most researches or engineers tend to adopt the smallest electric current density as 0.5 ASD to curb the so called mushroom-like structures. In this case, it costs about 230 minutes to have a thickness of approximately 70 um in 0.5 ASD. Although it's a simple method and a common practice, however, the coplanarity is still hard to be controlled as accurately as ±2.5 um, not to mention it requires longer electroplating time during the whole process. On the contrary, with the help of this polisher proposed in this invention, under the same conditions it allows turning the limiting electric current density to 2 ASD, sharply and effectively reducing the electroplating time from 230 minutes to 58 minutes.

The proposed polisher could polish four 4 inch silicon wafers at a time, and its material removal rate (MRR) ranges between 0.5 um/min and 0.7 um/min for the common Sn—Pb solder bumps, almost 50˜70 times faster than CMP.

Post-treatment after electroplating is involved in sodiumphosphate solution for at least 30˜60 s at a temperature ranging from 80° C. to 90° C. and dry the substrate 200 with N₂.

Referring to FIG. 2E, the first layer of bulged electroplated copper pillar 205 is subsequently planarized with a polisher to form the first layer of flat electroplated copper pillar 206. The sequences of this process are described as following: (1) Pad pre-wet, a process to rinse the soft polishing pad 305 before the start of each polishing action, is employed under flow rate at 300 ml/min until the soft polishing pad 305 is totally cleaned. (2) The substrate 200 is mounted on the polishing fixture 401. (3) Adjust desired polishing velocity and polishing time. (4) The polishing slurry 304 flow rate from the spray nozzle during polishing is set between 150 to 200 ml/min. (5) Employ a nylon brush along with DI water to scrub the surface of the soft polishing pad 305 so that the used polishing slurry 304 will not sink into the soft polishing pad 305. (6) Finally, the substrate 200 is rinsed with DI water and dried with N₂.

Referring to FIGS. 2F-2I, which, in essence, repeat the previous processes from FIGS. 2B-2E illustrate the fabrication of the second layer of the copper pillar 211. Firstly, define the second PR layer of copper pillar 207 up to the thickness of 20˜35 um to create the second opening hole 208. And then electroplate the second opening hole 208 over or at least has the same level as the second PR surface 207 with Sn—Pb or other Pb-free Sn-based metal or alloys such as pure Tin (Sn), Sn—Ag, Sn—Cu, Sn—Bi, Sn—Ag—Cu to create the second layer of electroplated copper pillar 209. Finally, change the electroplated copper pillar 209 into the flat polished copper pillar 210 by using the polisher.

Referring to FIG. 2J, both two PR layers 203, 207 and UBMs 201, 202 are stripped from the substrate 200 to turn into the flat double-layer electroplated copper pillar 211.

Referring to FIG. 2K, conduct the final reflow process for the reflowable copper pillar 211 to form the complete reflowed double-layer electroplated copper pillar 212.

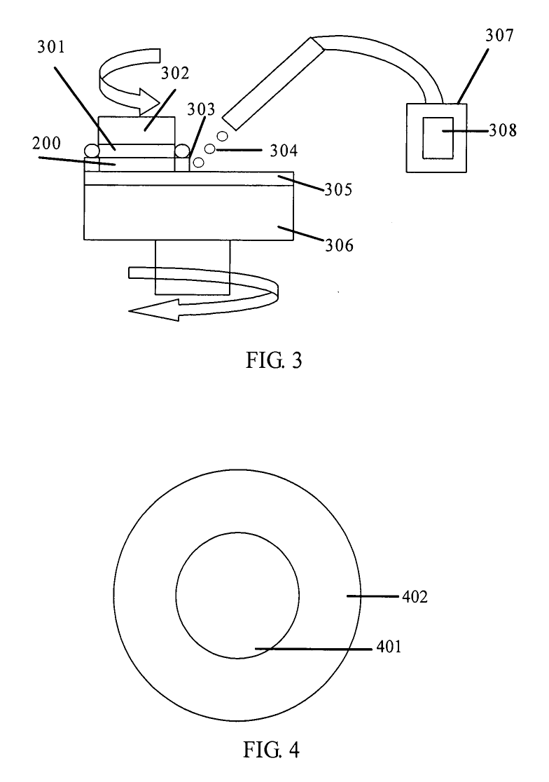

Referring to FIG. 3, reference numeral 200 is a substrate that is being polished. Reference numeral 301 is the polishing fixture. Reference numeral 302 is a loading pressure. Reference numeral 303 is the guiding wheel of the polisher, which acts as a rotary medium between the polishing fixture 301 and the polisher. Reference numeral 304 is the dipped polishing slurry. Reference numeral 305 is a soft polishing pad taped on the hard polishing platen 306. Reference numeral 307 and 308 are slurry container and turbine pump respectively. The polished substrate 200 fixed on the polishing fixture 301 is kept on the soft polishing pad 305.

Adding a suitable loading pressure 302 on the polishing fixture 301 is also available, which is beneficial to boost material removal rate (MRR) for any kinds of electroplated metals and alloys. However, exerting too heavy loading pressure may trigger slight vibration between the polishing fixture 301 and the guiding wheel 303 located at the central part of the polisher, causing relatively poorer polishing quality.

Referring to FIG. 4, Reference numeral 401 is a piece of flexible soft rubber tapped on the polishing fixture 301. Reference numeral 402 is a transparent PVC ring kept at the external rim of the polishing fixture 301.

Adding any fixing devices that could keep the polished substrate unmoved like a transparent PVC ring 402 on the external rim of the polishing fixture 301 could withstand the huge shearing stress during the whole polishing process so as to enhance the global polishing uniformity.

Although the invention has been described with reference to particular embodiments, the description is only an example of the invention's application and should not be taken as a limitation. Various adaptations and combinations of features of the embodiments disclosed are within the scope of the invention as defined by the following claims.

What is claimed is:

1. A method for controlling the coplanarity of multi-layer flip chip copper pillars based on the processes of multi-layer photolithography, electroplating, polishing, stripping PR and UBMs, and reflow, comprising the steps of:
(1) using a mask to give the layout of flip chip copper pillars on the substrate by photolithography process;
(2) depositing two separate layers of copper pillars in turn by using electroplating process inner the open holes defined after photolithography process;
(3) employing a polishing process to planarize the plated structures exceeded the PR surface throughout the whole substrate to control the height of the electroplated copper pillars;
(4) stripping PR and UBMs; and
(5) placing the polished copper pillars into the reflow oven to conduct reflow process, if necessary.

2. The method of claim 1, wherein in said step (2), the first layer out of the two separate layers of copper pillars is made of copper or other metals dispelling heat well such as Au (Gold), Ag (Silver) and Al (Aluminum).

3. The method of claim 1, wherein in said step (2), the second layer out of the two separate layers of copper pillars is made of Sn—Pb or other Pb-free Sn-based metals or alloys such as pure Sn, Sn—Ag, Sn—Cu, Sn—Bi, Sn—Ag—Cu.

4. The method of claim 1, wherein in said step (3), the height of the electroplated copper pillars could be precisely controlled to the desired and expectative dimension by means of a polishing mechanism.

5. A method for controlling the coplanarity of single-layer and multi-layer flip chip copper pillars by using a polisher equipped with a main platen, a hard polishing plate, a soft polishing pad, polishing slurry and a polishing holding fixture.

6. The method of claim 5, wherein the multi-layer refer to the electroplated flip chip copper pillars contain two layers or above.

7. The method of claim 5, wherein the hard polishing plate is made of stainless or cast iron.

8. The method of claim 5, wherein the soft polishing pad is made of non-woven or Polyurethane materials applicable to be taped on the hard polishing plate.

9. The method of claim 5, wherein the types of slurry composition in accordance with using varied polishing speeds, electroplated solder materials and hardness of the soft polishing pad are Al₂O₃, SiO₂, CeO₂ and ZrO₂.

10. The method of claim 5, wherein the surface of the polishing holding fixture is taped with a piece of flexible soft rubber and a fixing device that could fix the polished substrate unmoved like a PVC ring is placed on the rim of the flexible soft rubber.
